(19) United States
(12) Patent Application Publication
(10) Pub. No.: US 2024/0014230 A1
(43) Pub. Date: Jan. 11, 2024

(54) SOLID-STATE IMAGING ELEMENT, METHOD OF MANUFACTURING THE SAME, AND ELECTRONIC DEVICE

(71) Applicant: SONY SEMICONDUCTOR SOLUTIONS CORPORATION, Kanagawa (JP)

(72) Inventors: Masahiko ONO, Kumamoto (JP); Kentaro IMAMIZU, Kumamoto (JP)

(73) Assignee: SONY SEMICONDUCTOR SOLUTIONS CORPORATION, Kanagawa (JP)

(21) Appl. No.: 18/257,399

(22) PCT Filed: Dec. 10, 2021
(86) PCT No.: PCT/JP2021/045489

§ 371 Date: Jun. 14, 2023

(30) Foreign Application Priority Data
Dec. 25, 2020 (JP) 2020-216374

(51) Int. Cl. H01L 27/146

(52) U.S. Cl. CPC H01L 27/14614; H01L 27/14647; H01L 27/14689

(57) ABSTRACT

The present technology relates to a solid-state imaging element, a method of manufacturing the same, and an electronic device capable of implementing a stacked structure of a plurality of photodiodes, thereby improving sensitivity. A solid-state imaging element according to the present technology includes a plurality of photodiodes stacked in a semiconductor substrate in a thickness direction of the semiconductor substrate, and a transistor including a gate electrode at least a part of which is embedded in the semiconductor substrate, the transistor that individually reads a signal charge accumulated in each of the plurality of photodiodes according to a voltage applied to the gate electrode. The present technology is applicable to, for example, an imaging device.

### TECHNICAL FIELD

The present technology relates to a solid-state imaging element, a method of manufacturing the same, and an electronic device, and especially relates to a solid-state imaging element capable of implementing a stacked structure of a plurality of photodiodes, thereby improving sensitivity, a method of manufacturing the same, and an electronic device.

### BACKGROUND ART

In the conventional image sensor, for example, a red (R), green (G), or blue (B) color filter is provided in each pixel, and a signal charge corresponding to light of one color of R, G, and B is generated by one photodiode provided in each pixel to be output. In a configuration using such color filter, deterioration in sensitivity due to a significant loss of an amount of light reaching a photodiode causes a problem.

Recently, in an image sensor, a pixel region per pixel has been decreased due to miniaturization of a pixel. In this case, a decrease in signal charge capacity of the photodiode causes a problem. In order to increase the signal charge capacity of the photodiode, a wide pixel region is required, and there is a trade-off between miniaturization of pixels and an increase in signal charge capacity.

In order to suppress the decrease in signal charge capacity, a technology of generating signal charges corresponding to respective colors of R, G, and B in one pixel to output by utilizing a penetration depth of light into a silicon substrate without providing a color filter in the pixel is devised.

Specifically, a structure in which a photodiode for obtaining a signal charge corresponding to blue light, a photodiode for obtaining a signal charge corresponding to green light, and a photodiode for obtaining a signal charge corresponding to red light are stacked in one pixel in a thickness direction of a silicon substrate from a light-receiving surface side is proposed (Patent Documents 1 and 2).

### CITATION LIST

### Patent Document

Patent Document 1: Japanese Patent Application Laid-Open No. 2014-225560
Patent Document 2: Japanese Patent Application Laid-Open No. 2015-146364

### SUMMARY OF THE INVENTION

### Problems to be Solved by the Invention

However, in the structures disclosed in Patent Documents 1 and 2, in order to individually read signal charges from a plurality of stacked photodiodes, it has been necessary to form one vertical transistor for one photodiode. In other words, in a case of a structure in which three photodiodes are stacked in one pixel, it has been necessary to form three vertical transistors.

Furthermore, the structure disclosed in Patent Document 2 is a structure in which a vertical transistor is embedded in a semiconductor layer, and it is necessary to form a semiconductor layer by epitaxial growth after the photodiode is formed, and process implementation is considered to be difficult.

The present technology has been achieved in view of such circumstances, and is intended to implement the stacked structure of the plurality of photodiodes and improve the sensitivity.

### Solutions to Problems

A solid-state imaging element according to a first aspect of the present technology includes a plurality of photodiodes stacked in a semiconductor substrate in a thickness direction of the semiconductor substrate, and a transistor including a gate electrode at least a part of which is embedded in the semiconductor substrate, the transistor that individually reads a signal charge accumulated in each of the plurality of photodiodes according to a voltage applied to the gate electrode.

A method of manufacturing a solid-state imaging element according to a second aspect of the present technology includes stacking a plurality of photodiodes in a semiconductor substrate in a thickness direction of the semiconductor substrate, and forming a transistor including a gate electrode at least a part of which is embedded in the semiconductor substrate, the transistor that individually reads a signal charge accumulated in each of the plurality of photodiodes according to a voltage applied to the gate electrode.

An electronic device according to a third aspect of the present technology includes a solid-state imaging element including a plurality of photodiodes stacked in a semiconductor substrate in a thickness direction of the semiconductor substrate, and a transistor including a gate electrode at least a part of which is embedded in the semiconductor substrate, the transistor that individually reads a signal charge accumulated in each of the plurality of photodiodes according to a voltage applied to the gate electrode.

In the first to third aspects of the present technology, a plurality of photodiodes stacked in a semiconductor substrate in a thickness direction of the semiconductor substrate, and a transistor including a gate electrode at least a part of which is embedded in the semiconductor substrate, the transistor that individually reads a signal charge accumulated in each of the plurality of photodiodes according to a voltage applied to the gate electrode are provided.

In the second aspect of the present technology, a plurality of photodiodes is stacked in a semiconductor substrate in a thickness direction of the semiconductor substrate, and a transistor including a gate electrode at least a part of which is embedded in the semiconductor substrate, the transistor that individually reads a signal charge accumulated in each of the plurality of photodiodes according to a voltage applied to the gate electrode is formed.

### BRIEF DESCRIPTION OF DRAWINGS

FIG. 1 is a diagram illustrating a schematic configuration example of a solid-state imaging element to which the present technology is applied.

FIG. 2 is a schematic cross-sectional view of a pixel of the solid-state imaging element.

FIG. 3 is a diagram illustrating an example of an equivalent circuit of the pixel.

FIG. 4 is a cross-sectional view illustrating a first structure of a vertical transistor.

FIG. 5 is a diagram illustrating an example of a flow of reading signal charges accumulated in photodiodes and a potential image.

FIG. 6 is a diagram illustrating an example of a flow of reading signal charges accumulated in photodiodes and a potential image.

FIG. 7 is a cross-sectional view illustrating a second structure of the vertical transistor.

FIG. 8 is a cross-sectional view illustrating a third structure of the vertical transistor.

FIG. 9 is a diagram for explaining a method of forming the pixel including the vertical transistor according to the first structure.

FIG. 10 is a diagram for explaining a method of forming the pixel including the vertical transistor according to the first structure.

FIG. 11 is a diagram for explaining a method of forming the pixel including the vertical transistor according to the first structure.

FIG. 12 is a diagram for explaining a method of forming the pixel including the vertical transistor according to the first structure.

FIG. 13 is a diagram for explaining a method of forming the pixel including the vertical transistor according to the first structure.

FIG. 14 is a diagram for explaining a method of forming the pixel including the vertical transistor according to the first structure.

FIG. 15 is a diagram for explaining a method of forming the pixel including the vertical transistor according to the second structure.

FIG. 16 is a diagram for explaining a method of forming the pixel including the vertical transistor according to the second structure.

FIG. 17 is a diagram for explaining a method of forming the pixel including the vertical transistor according to the third structure.

FIG. 18 is a cross-sectional view illustrating a first variation of the pixel.

FIG. 19 is a plan view of the semiconductor substrate in which a plurality of pixels according to the first variation is arranged as seen from a circuit formation surface side.

FIG. 20 is a cross-sectional view illustrating a second variation of the pixel.

FIG. 21 is a cross-sectional view illustrating a third variation of the pixel.

FIG. 22 is a cross-sectional view illustrating a fourth variation of the pixel.

FIG. 23 is a cross-sectional view illustrating a fifth variation of the pixel.

FIG. 24 is a block diagram depicting a configuration example of an imaging device as an electronic device to which the technology of an embodiment of the present disclosure is applied.

FIG. 25 is a diagram for explaining a usage example of the imaging device to which the technology of an embodiment of the present disclosure is applied.

FIG. 26 is a block diagram depicting an example of schematic configuration of a vehicle control system.

FIG. 27 is a diagram of assistance in explaining an example of installation positions of an outside-vehicle information detecting section and an imaging section.

### MODE FOR CARRYING OUT THE INVENTION

Hereinafter, a mode for carrying the present technology is described. The description is given in the following order.

1. Embodiment of Solid-State Imaging Element

2. Method of Forming Pixel

3. Variation

4. Application Example to Electronic Device

5. Usage Example of Imaging Device

6. Application Example to Mobile Body

<<1. Embodiment of Solid-State Imaging Element>>

<Schematic External View>

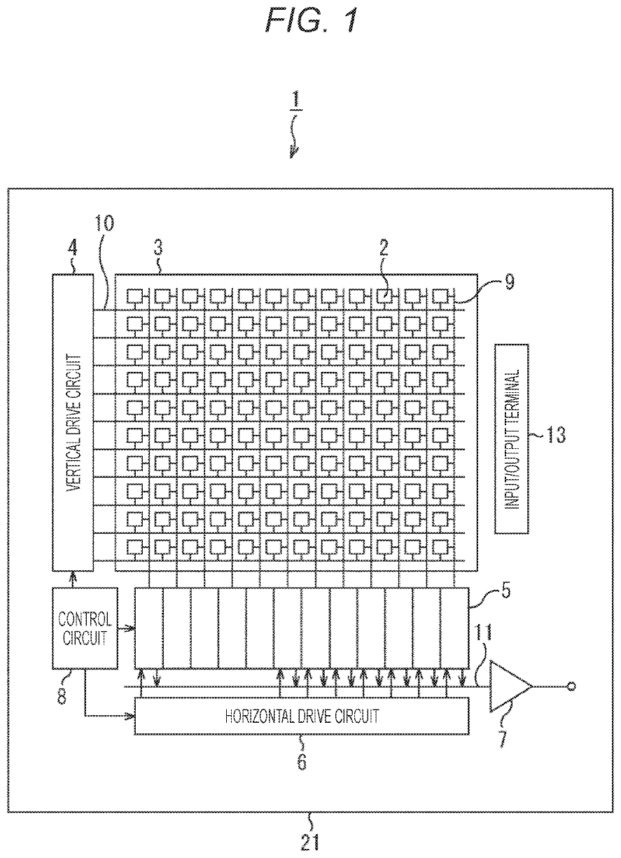

FIG. 1 is a diagram illustrating a schematic configuration example of a solid-state imaging element 1 to which the present technology is applied.

The solid-state imaging element 1 in FIG. 1 includes a pixel array unit 3 obtained by arranging pixels 2 in a two-dimensional array on a semiconductor substrate 21 including silicon (Si), for example, as a semiconductor, and a peripheral circuit unit around the same. The peripheral circuit unit includes a vertical drive circuit 4, a column signal processing circuit 5, a horizontal drive circuit 6, an output circuit 7, a control circuit 8 and the like.

The pixel 2 includes a photodiode as a photoelectric conversion element, a plurality of pixel transistors and the like. The plurality of pixel transistors includes four MOS transistors, which are a transfer transistor, a selection transistor, a reset transistor, and an amplification transistor, for example.

The control circuit 8 receives an input clock and data that indicates an operation mode and the like, and outputs data such as internal information of the solid-state imaging element 1. That is, the control circuit 8 generates a clock signal and a control signal that serve as a reference for operations of the vertical drive circuit 4, the column signal processing circuit 5, the horizontal drive circuit 6 and the like on the basis of a vertical synchronization signal, a horizontal synchronization signal, and a master clock. Then, the control circuit 8 outputs the generated clock signal and control signal to the vertical drive circuit 4, the column signal processing circuit the horizontal drive circuit 6 and the like.

The vertical drive circuit 4 includes, for example, a shift register, selects predetermined pixel drive wiring 10, supplies a pulse for driving the pixel 2 to the selected pixel drive wiring and drives the pixels 2 row by row. That is, the vertical drive circuit 4 sequentially selects to scan the pixels 2 of the pixel array unit 3 in a vertical direction row by row to supply the column signal processing circuit 5 via a vertical signal line 9 with a pixel signal based on a signal charge generated according to an amount of received light in the photoelectric conversion element of each pixel 2.

The column signal processing circuit 5 arranged for each column of the pixels 2 performs signal processing such as noise removal on the signals output from the pixels 2 of one column for each pixel column. For example, the column signal processing circuit 5 performs signal processing such as correlated double sampling (CDS) for removing pixel-specific fixed pattern noise, AD conversion and the like.

The horizontal drive circuit 6 including a shift register, for example, selects the column signal processing circuits 5 in turn by sequentially outputting horizontal scanning pulses and allows each of the column signal processing circuits 5 to output the pixel signal to a horizontal signal line 11.

The output circuit 7 performs predetermined signal processing on the signals sequentially supplied from each of the column signal processing circuits 5 via the horizontal signal line 11 to output. For example, there is a case where the output circuit 7 performs only buffering or performs various kinds of digital signal processing such as black level adjustment or column variation correction. An input/output terminal 13 exchanges signals with the outside.

The solid-state imaging element 1 formed in the above-described manner is a CMOS image sensor referred to as a column AD type in which the column signal processing circuit 5 that performs the CDS processing and AD conversion processing is arranged for each pixel column.

Furthermore, the solid-state imaging element 1 also is a backside illumination MOS solid-state imaging element on which light is incident from a rear surface side on a side opposite to a front surface side of the semiconductor substrate 21 on which the pixel transistor is formed.

<Basic Structure of Pixel>

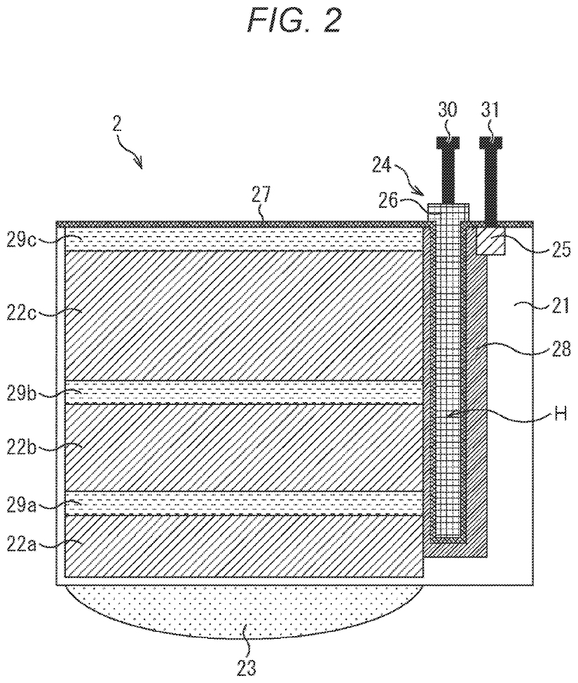

FIG. 2 is a schematic cross-sectional view of the pixel 2 of the solid-state imaging element 1.

In the pixel 2, as illustrated in FIG. 2, three photodiodes 22a to 22c are stacked in the semiconductor substrate 21 including silicon, for example, in a thickness direction of the substrate. The semiconductor substrate 21 includes, for example, a low-concentration P-type (first conductivity type) impurity region. In FIG. 2, one surface on an upper side of the semiconductor substrate 21 serves as a circuit formation surface, and a multilayer wiring layer not illustrated is formed on the circuit formation surface. One surface on a lower side opposite to the circuit formation surface of the semiconductor substrate 21 serves as a light-receiving surface, and an on-chip lens 23 is provided on the light-receiving surface side.

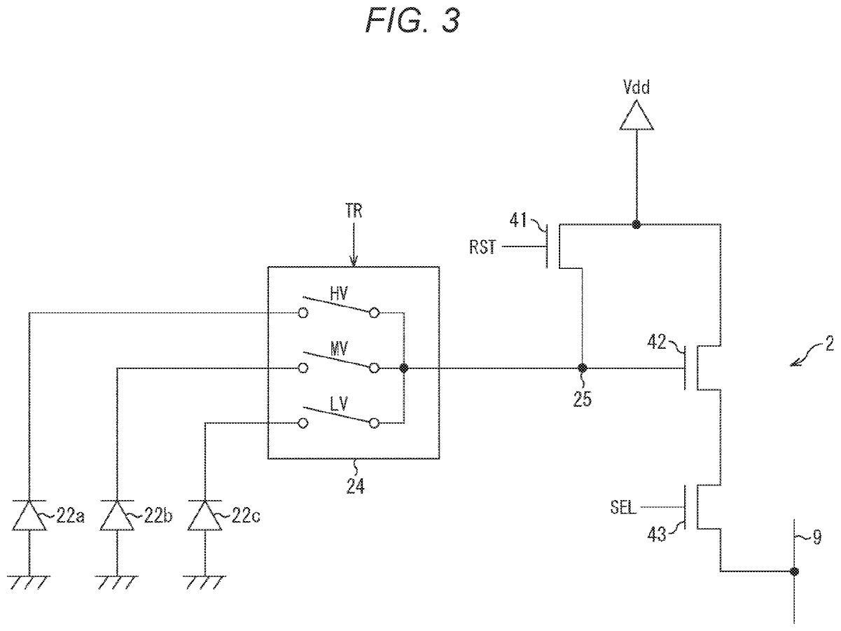

On the circuit formation surface of the semiconductor substrate 21, a vertical transistor 24 for reading signal charges from the photodiodes 22a to 22c, and a floating diffusion (FD) 25 that accumulates the read signal charges are formed. Note that, a reset transistor 41, an amplification transistor 42, a selection transistor 43 and the like (FIG. 3) not illustrated are also formed on the circuit formation surface besides them.

The photodiodes 22a to 22c are, for example, photoelectric conversion layers, each including a high-concentration N-type (second conductivity type) impurity region, that generate and accumulate the signal charge corresponding to the amount of received light by PNA junction with element isolation layers 29a to 29c formed using a high-concentration P-type impurity region, respectively. The photodiodes 22a to 22c absorb and photoelectrically convert light of different wavelengths to generate signal charges, for example.

The element isolation layer 29a is formed between the photodiode 22a and the photodiode 22b, and the element isolation layer 29b is formed between the photodiode 22b and the photodiode 22c. Furthermore, the element isolation layer 29c is formed between an interface of the circuit formation surface of the semiconductor substrate 21 and the photodiode 22c.

Light incident on the pixel 2 reaches a deeper portion of the semiconductor substrate 21 as a wavelength becomes longer. For example, blue light incident on the pixel 2 reaches a depth of 0.2 to 0.5 μm from the light-receiving surface of the semiconductor substrate 21. The photodiode 22a is formed at a depth of 0.2 to 0.5 μm from the light-receiving surface of the semiconductor substrate 21, and selectively absorbs the blue light (short-wavelength light) to perform photoelectric conversion. In other words, the photodiode 22a is a photodiode for obtaining the signal charge corresponding to the blue light.

Green light incident on the pixel 2 reaches a depth of 0.5 to 1.5 μm from the light-receiving surface of the semiconductor substrate 21. The photodiode 22b is formed at a depth of 0.5 to 1.5 μm from the light-receiving surface of the semiconductor substrate 21, and selectively absorbs the green light (middle-wavelength light) to perform photoelectric conversion. In other words, the photodiode 22b is a photodiode for obtaining the signal charge corresponding to the green light.

Red light incident on the pixel 2 reaches a depth of 1.5 to 3 μm from the light-receiving surface of the semiconductor substrate 21. The photodiode 22c is formed at a depth of 1.5 to 3 μm from the light-receiving surface of the semiconductor substrate 21, and selectively absorbs the red light (long-wavelength light) to perform photoelectric conversion. In other words, the photodiode 22c is a photodiode for obtaining the signal charge corresponding to the red light.

The vertical transistor 24 is formed adjacent to a region formed by stacking the three photodiodes 22a to 22c. The vertical transistor 24 serves as a transfer transistor that transfers the signal charges accumulated in the photodiodes 22a to 22c to the FD 25. The vertical transistor 24 includes a gate electrode 26 at least a part of which is embedded in the semiconductor substrate 21. The gate electrode 26 is formed in a recess H dug in a depth direction of the semiconductor substrate 21 via a gate insulating film 27.

The gate electrode 26 includes, for example, a conductive film material such as polysilicon doped with n-type or p-type impurities at high concentration, and is connected to wiring 30 for supplying a voltage to the gate electrode 26.

Furthermore, the vertical transistor 24 includes a charge transfer layer 28 between the gate electrode 26, and the photodiodes 22a to 22c and the FD 25. More specifically, the charge transfer layer 28 is formed so as to surround a side surface and a bottom surface of the gate electrode 26 embedded in the recess H via the gate insulating film 27. The charge transfer layer 28 forms a transfer path of the signal charges from the photodiodes 22a to 22c to the FD 25. The charge transfer layer 28 includes a high-concentration impurity region of the same conductivity type as that of the photodiodes 22a to 22c, which are the photoelectric conversion layers, that is, an N-type. In the vertical transistor 24, for example, the photodiodes 22a to 22c serve as a source, and the FD 25 serves as a drain.

The FD 25 is a signal charge holding unit that holds the signal charges read from the photodiodes 22a to 22c. The FD 25 includes a high-concentration N-type impurity region. The FD 25 is connected to read wiring 31 formed on a multilayer wiring layer on the circuit formation surface, and the signal charges transferred to the FD 25 by the vertical transistor 24 are output to the column signal processing circuit 5 via the read wiring 31.

As described above, in the pixel 2, one vertical transistor 24 is formed for the stacked three photodiodes 22a to 22c. The vertical transistor 24 may individually read the signal charges accumulated in the photodiodes 22a to 22c according to the voltage applied to the gate electrode 26 via the wiring 30. Note that, the structure of the pixel 2 illustrated in FIG. 2 is a schematic structure for explaining that it is sufficient to provide one vertical transistor 24 for the three photodiodes 22a to 22c, and a detailed structure of the vertical transistor 24 that may be used for individually reading the signal charges from the respective photodiodes 22a to 22c is to be described later.

<Circuit Configuration Example of Pixel>

FIG. 3 is a diagram illustrating an example of the equivalent circuit of the pixel 2.

As illustrated in FIG. 3, the pixel 2 includes the photodiodes 22a to 22c, the vertical transistor 24, the FD 25, the reset transistor 41, the amplification transistor 42, and the selection transistor 43.

An anode terminal of each of the photodiodes 22a to 22c is grounded, and a cathode terminal thereof is connected to the FD 25 via the vertical transistor 24.

When the vertical transistor 24 is turned on by a transfer signal TR supplied to the gate electrode 26, this reads the signal charge generated by any one of the photodiodes 22a to 22c and transfers the same to the FD 25. Here, the vertical transistor 24 divides a control voltage supplied to the gate electrode 26 as the transfer signal TR into a low voltage LV, a medium voltage MV, and a high voltage HV (LV<MV<HV), thereby reading the signal charges generated by the photodiodes 22a to 22c in turn and transferring the same to the FD 25. More specifically, first, when the transfer signal TR of the low voltage LV is supplied to the gate electrode 26, a path to the photodiode 22c is connected, and the signal charge accumulated in the photodiode 22c is read. Next, when the transfer signal TR of the medium voltage MV is supplied to the gate electrode 26, a path to the photodiodes 22b and 22c is connected, and since the accumulated charge of the photodiode 22c is already read, the signal charge accumulated in the photodiode 22b is read. Finally, when the transfer signal TR of the high voltage HV is supplied to the gate electrode 26, a path to the photodiodes 22a to 22c is connected, and since the accumulated charges of the photodiodes 22b and 22c are already read, the signal charge accumulated in the photodiode 22a is read.

The FD 25 holds the signal charge read from any one of the photodiodes 22a to 22c.

When the reset transistor 41 is turned on by a reset signal RST, this allows the FD 25 to discharge the signal charge held therein to a constant voltage source Vdd, thereby resetting a potential of the FD 25.

The amplification transistor 42 outputs the pixel signal corresponding to the potential of the FD 25. That is, the amplification transistor 42 forms a source follower circuit along with a load MOS (not illustrated) as a constant current source, and outputs the pixel signal indicating a level corresponding to the signal charge held in the FD 25 to the column signal processing circuit 5 via the selection transistor 43.

The selection transistor 43 is turned on when the pixel 2 is selected by a selection signal SEL, and outputs the pixel signal of the pixel 2 to the column signal processing circuit 5 via the vertical signal line 9. The transfer signal TR, the reset signal RST, and the selection signal SEL are controlled by the vertical drive circuit 4 and supplied via the pixel drive wiring 10.

Note that, the circuit configuration of the pixel 2 is not limited to the configuration illustrated in FIG. 2.

<Detailed Structural Example of Vertical Transistor 24>

First Structural Example (Stage Structure of Gate Insulating Film 27 Having Different Film Thicknesses)

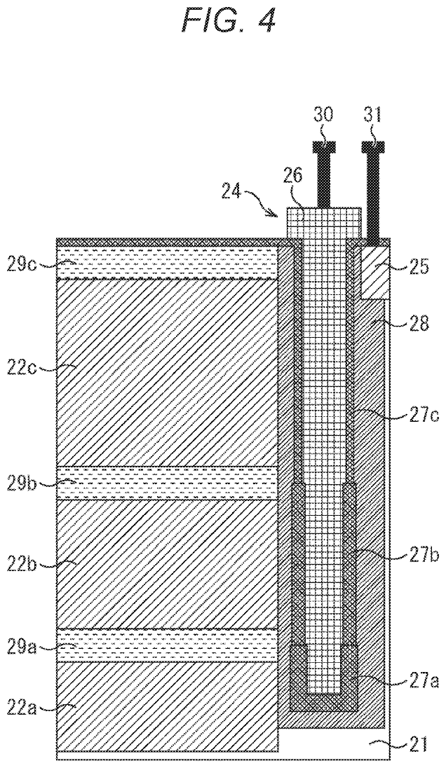

FIG. 4 is an enlarged cross-sectional view of the vicinity of the vertical transistor 24 of the pixel 2, the cross-sectional view illustrating a first structure of the vertical transistor 24.

In the first structure of the vertical transistor 24, as illustrated in FIG. 4, the gate insulating film 27 includes three stages of gate insulating films 27a to 27c having different film thicknesses in a substrate plane direction. The gate insulating films 27a to 27c correspond to the photodiodes 22a to 22c, respectively, and are formed in such a manner that the film thickness in the substrate plane direction increases in the order of the gate insulating film 27c, the gate insulating film 27b, and the gate insulating film 27a (gate insulating film 27c<gate insulating film 27b<gate insulating film 27a).

The gate insulating film 27a having the largest film thickness is formed with a uniform film thickness with respect to the photodiode 22a between a depth at which the photodiode 22a is formed and a depth at which the element isolation layer 29a is formed. The gate insulating film 27b having the second largest film thickness is formed with a uniform film thickness with respect to the photodiode 22b between the depth at which the element isolation layer 29a is formed and a depth at which the element isolation layer 29b is formed. The gate insulating film 27c having the smallest film thickness is formed from the depth at which the element isolation layer 29b is formed to the circuit formation surface of the semiconductor substrate 21, and is also formed on the circuit formation surface on an upper side of the element isolation layer 29c. The gate insulating film 27c is formed with a uniform film thickness with respect to the photodiode 22c.

By forming the gate insulating films 27a to 27c having different film thicknesses corresponding to the photodiodes 22a to 22c, a difference occurs in voltage at which reading of the signal charge accumulated in each of the photodiodes 22a to 22c starts. Specifically, when the transfer signal TR of the low voltage LV is applied to the gate electrode 26 via the wiring 30, the reading of the signal charge from the photodiode 22c is started, and when the transfer signal TR of the medium voltage MV is applied, the reading of the signal charge from the photodiode 22b is started. When the transfer signal TR of the high voltage HV is applied, the reading of the signal charge from the photodiode 22a is started.

Therefore, by controlling the voltage applied to the gate electrode 26 of the vertical transistor 24, it becomes possible to read the signal charges in the order of the photodiode 22c, the photodiode 22b, and the photodiode 22a. In other words, the signal charges corresponding to the red light, green light, and blue light may be individually read.

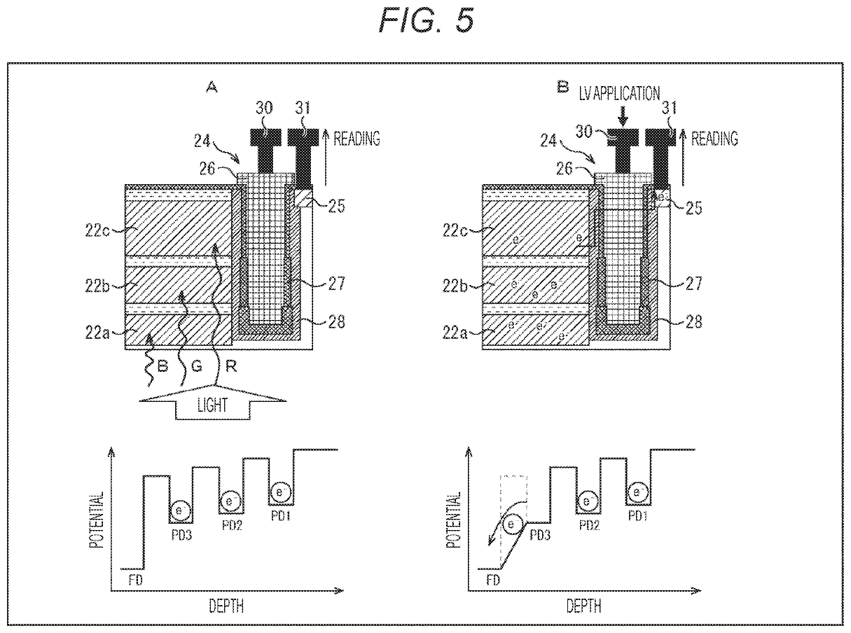

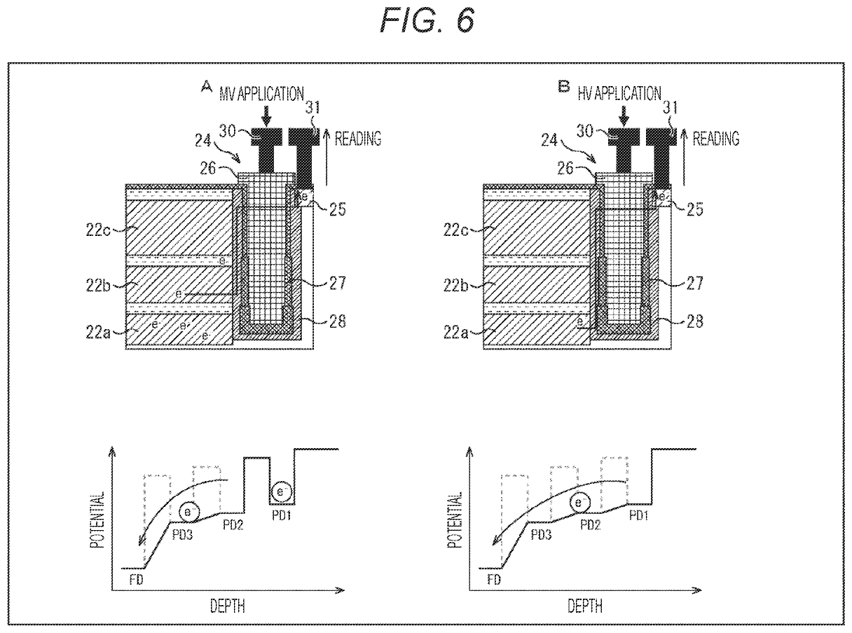

FIGS. 5 and 6 are diagrams illustrating an example of a flow of reading the signal charges accumulated in the photodiodes 22a to 22c and a potential image.

As illustrated in an upper side in A of FIG. 5, in a case where the pixel 2 is irradiated with light, the photodiode 22a (PD1) absorbs the blue light, the photodiode 22b (PD2) absorbs the green light, and the photodiode 22c (PD3) absorbs the red light.

The photoelectric conversion is performed in each of the photodiodes 22a to 22c, so that the charges corresponding to the amounts of received blue light, green light, and red light are accumulated. As illustrated in the potential image on a lower side in A of FIG. 5, the potential of each of the photodiodes 22a to 22c is shallowest in the photodiode 22c (PD3), and is deeper in the order of the photodiode 22b (PD2) and the photodiode 22a (PD1).

Therefore, first, as illustrated in an upper side in B of FIG. 5, the transfer signal TR of the low voltage LV is applied to the gate electrode 26 of the vertical transistor 24 via the wiring so that a read path connected from the photodiode 22c (PD3) having the shallowest potential to the FD 25 is formed as illustrated in the potential image on a lower side in B of FIG. 5, and the signal charge accumulated in the photodiode 22c is read to the FD 25.

Next, as illustrated in an upper side in A of FIG. 6, the transfer signal TR of the medium voltage MV is applied to the gate electrode 26 of the vertical transistor 24 via the wiring 30, so that a read path connected from the photodiode 22b (PD2) having the next shallowest potential to the FD 25 is additionally formed as illustrated in the potential image on a lower side in A of FIG. 6, and the signal charge accumulated in the photodiode 22b is read to the FD 25.

Next, as illustrated in an upper side in B of FIG. 6, the transfer signal TR of the high voltage HV is applied to the gate electrode 26 of the gate electrode 26 via the wiring 30, so that a read path connected from the photodiode 22a (PD1) having the deepest potential to the FD 25 is additionally formed as illustrated in the potential image on a lower side in B of FIG. 6, and the signal charge accumulated in the photodiode 22c is read to the FD 25.

As described above, the signal charges may be individually read from each of the three photodiodes 22a to 22c by using only one vertical transistor 24 formed for the three photodiodes 22a to 22c formed in a stacking manner.

Conventionally, in order to individually read the signal charges from a plurality of stacked photodiodes, the transfer transistors as many as the stacked photodiodes are required, but in the first structure, the signal charges may be individually read by one vertical transistor 24 regardless of the number of stacked photodiodes. This makes it possible to form a wider photoelectric conversion region than that in a case where a plurality of transfer transistors is formed, so that signal charge capacity may be increased and sensitivity may be improved.

Second Structure Example (Stage Structure of Charge Transfer Layer 28 Having Different Impurity Concentrations)

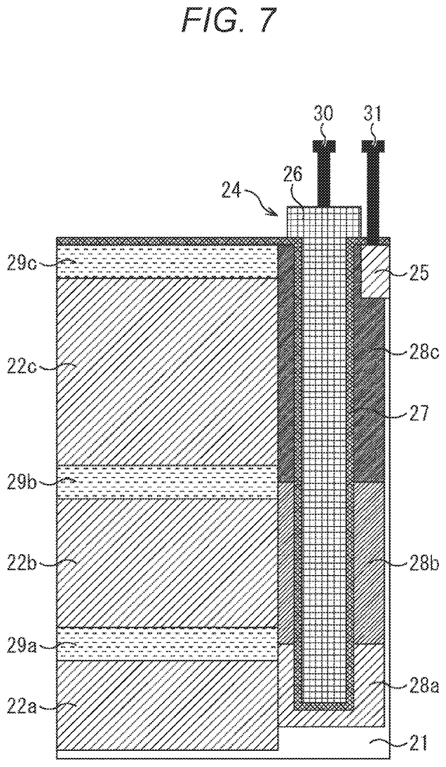

FIG. 7 is an enlarged cross-sectional view of the vicinity of the vertical transistor 24 of the pixel 2, the cross-sectional view illustrating a second structure of the vertical transistor 24.

In the second structure of the vertical transistor 24, as illustrated in FIG. 7, the charge transfer layer 28 includes three stages of charge transfer layers 28a to 28c having different impurity concentrations. The charge transfer layers 28a to 28c correspond to the photodiodes 22a to 22c, respectively, and are formed, for example, in such a manner that the impurity concentration increases in the order of the charge transfer layer 28a, the charge transfer layer 28b, and the charge transfer layer 28c (charge transfer layer 28a<charge transfer layer 28b<charge transfer layer 28c). Note that, the film thickness of the gate insulating film 27 in the substrate plane direction is the same at depth positions of the photodiodes 22a to 22c unlike in the first structure.

The charge transfer layer 28a having the lowest impurity concentration is formed at a uniform impurity concentration with respect to the photodiode 22a between the depth at which the photodiode 22a is formed and the depth at which the element isolation layer 29a is formed. The charge transfer layer 28b having the second lowest impurity concentration is formed at a uniform impurity concentration with respect to the photodiode 22b between the depth at which the element isolation layer 29a is formed and the depth at which the element isolation layer 29b is formed. The charge transfer layer 28c having the highest impurity concentration is formed at a uniform impurity concentration with respect to the photodiode 22c between the depth at which the element isolation layer 29b is formed and the depth at which the circuit formation surface on the upper side of the element isolation layer 29c is formed.

By forming the charge transfer layers 28a to 28c having different impurity concentrations corresponding to the photodiodes 22a to 22c, a difference occurs in voltage at which the reading of the signal charge accumulated in each of the photodiodes 22a to 22c starts as in the first structure of the vertical transistor 24. Therefore, by controlling the voltage applied to the gate electrode 26 of the vertical transistor 24, it becomes possible to read the signal charges in the order of the photodiode 22c, the photodiode 22b, and the photodiode 22a.

In the second structure, as in the first structure, the signal charges may be individually read by one vertical transistor 24 regardless of the number of stacked photodiodes. This makes it possible to form a wider photoelectric conversion region than that in a case where a plurality of transfer transistors is formed, so that signal charge capacity may be increased and sensitivity may be improved.

Third Structural Example (Stage Structure of Photodiodes 22a to 22c Having Different Distances from Vertical Transistor 24)

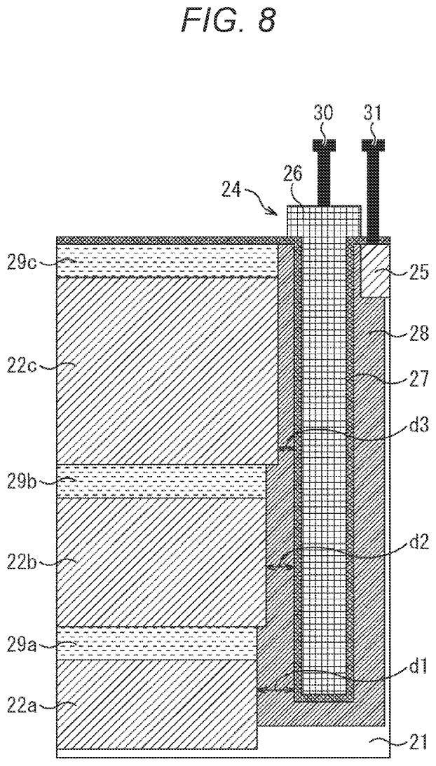

FIG. 8 is an enlarged cross-sectional view of the vicinity of the vertical transistor 24 of the pixel 2, the cross-sectional view illustrating a third structure of the vertical transistor 24.

In the third structure of the vertical transistor 24, as illustrated in FIG. 8, the photodiodes 22a to 22c are formed at different distances from the gate electrode 26 and the gate insulating film 27 of the vertical transistor 24. When a distance d3 between the photodiode 22c and the gate insulating film 27, a distance d2 between the photodiode 22b and the gate insulating film 27, and a distance d1 between the photodiode 22a and the gate insulating film 27 are compared with one another, they are formed in such a manner that the distance from the gate insulating film 27 increases in the order of the distance d3, the distance d2, and the distance d1 (distance d3<distance d2<distance d1). Note that, the film thickness of the gate insulating film 27 in the substrate plane direction is the same at the depth positions of the photodiodes 22a to 22c unlike in the first structure, and the impurity concentration of the charge transfer layers 28a to 28c is the same at the depth positions of the photodiodes 22a to 22c unlike in the second structure.

The charge transfer layer 28 is formed in a region between the photodiodes 22a to 22c and the gate insulating film 27. Furthermore, a distance between the element isolation layer 29a and the gate insulating film 27 is the same distance d1 as that of the photodiode 22a, and a distance between the element isolation layer 29b and the gate insulating film 27 is the same distance d2 as that of the photodiode 22b. A distance between the element isolation layer 29c and the gate insulating film 27 is the same distance d3 as that of the photodiode 22c.

By forming the photodiodes 22a to 22c in such a manner that the distances from the gate electrode 26 and the gate insulating film 27 of the vertical transistor 24 are different, a difference occurs in voltage at which reading of the signal charge accumulated in each of the photodiodes 22a to 22c starts as in the first and second structures. Therefore, by controlling the voltage applied to the gate electrode 26 of the vertical transistor 24, it becomes possible to read the signal charges in the order of the photodiode 22c, the photodiode 22b, and the photodiode 22a.

In the third structure, as in the first and second structures, the signal charges may be individually read by one vertical transistor 24 regardless of the number of stacked photodiodes. This makes it possible to form a wider photoelectric conversion region than that in a case where a plurality of transfer transistors is formed, so that signal charge capacity may be increased and sensitivity may be improved.

In FIG. 8, the example in which the distance increases in the order of the distance d3, the distance d2, and the distance d1 is described, but it is not necessary that the order of the distances d1 to d3 is the same as the stacking order of the photodiodes 22a to 22c.

For example, the photodiodes 22a to 22c may be formed in such a manner that the distance increases in the order of the distance d1, the distance d2, and the distance d3. In this case, the signal charges are read in the order of the photodiode 22a, the photodiode 22b, and the photodiode 22c.

According to the pixel 2 including the three photodiodes 22a to 22c stacked in the thickness direction of the substrate and the vertical transistor 24 having any one of the first to third structures described above, the signal charges accumulated in the three photodiodes 22a to 22c may be individually read by the one vertical transistor 24. This makes it possible to form a wider photoelectric conversion region than that in a case where a plurality of transfer transistors is formed, so that the signal charge capacity may be increased and the sensitivity may be improved. That is, a stacked structure of a plurality of photodiodes may be implemented, and the sensitivity may be improved.

<<2. Method of Forming Pixel>>

### First Structural Example

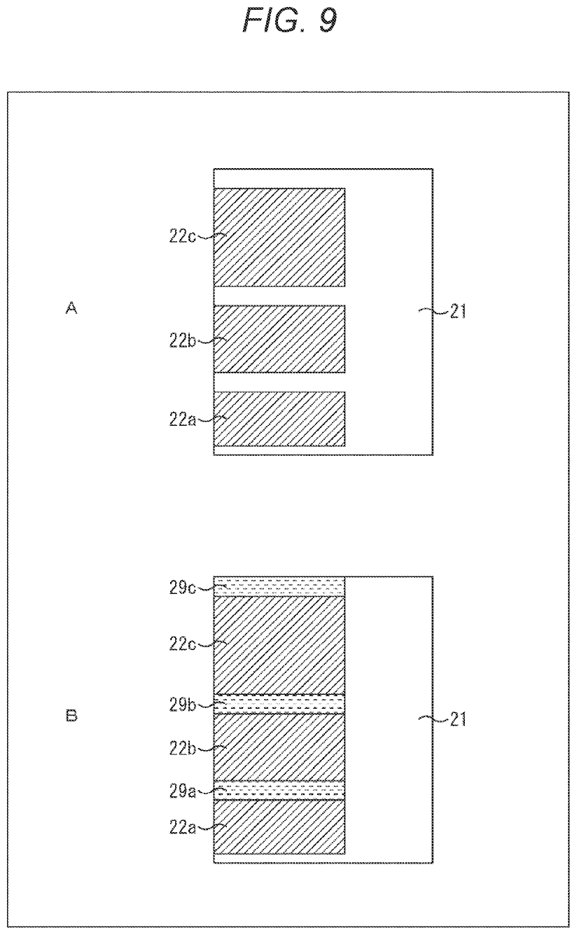

Next, a method of forming the pixel 2 including the vertical transistor 24 according to the first structure is described with reference to FIGS. 9 to 14.

First, as illustrated in A of FIG. 9, by doping the semiconductor substrate 21 with n-type impurities by ion implantation or the like, the photodiodes 22a to 22c are formed at different depths of the semiconductor substrate 21.

Next, as illustrated in B of FIG. 9, by doping the semiconductor substrate 21 with p-type impurities by ion implantation or the like, the element isolation layers 29a to 29c that isolate the photodiodes 22a to 22c, respectively, are formed.

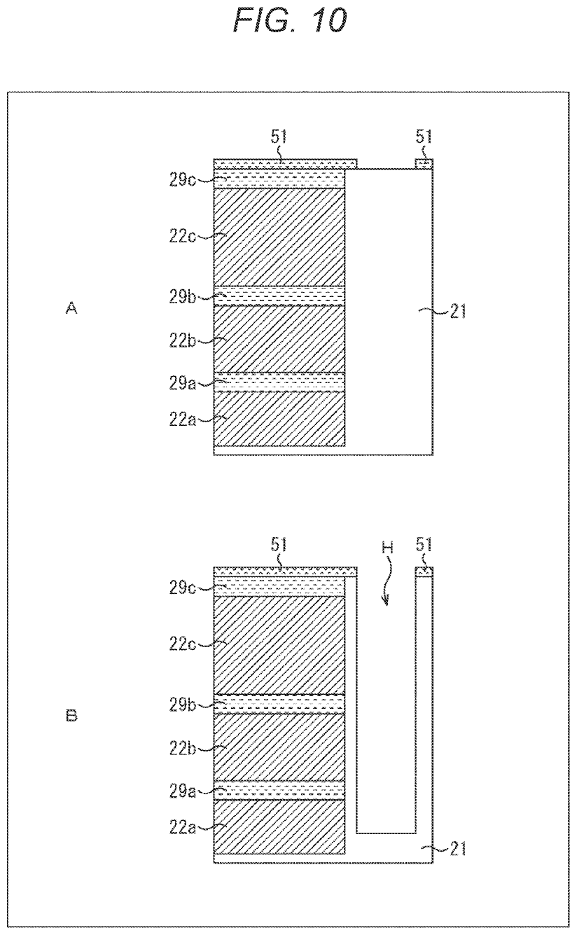

Next, as illustrated in A of FIG. 10, a mask 51 including silicon oxide and the like is formed by a CVD method or the like on the circuit formation surface of the semiconductor substrate 21 in which the photodiodes 22a to 22c and the element isolation layers 29a to 29c are formed. An opening for forming the recess H is formed on the mask 51 by a photolithography method or the like.

Next, as illustrated in B of FIG. 10, the recess H is formed in the semiconductor substrate 21 by dry etching or the like. At that time, the recess H is formed in such a manner that the depth of a bottom surface thereof reaches between an upper end and a lower end of the photodiode 22a.

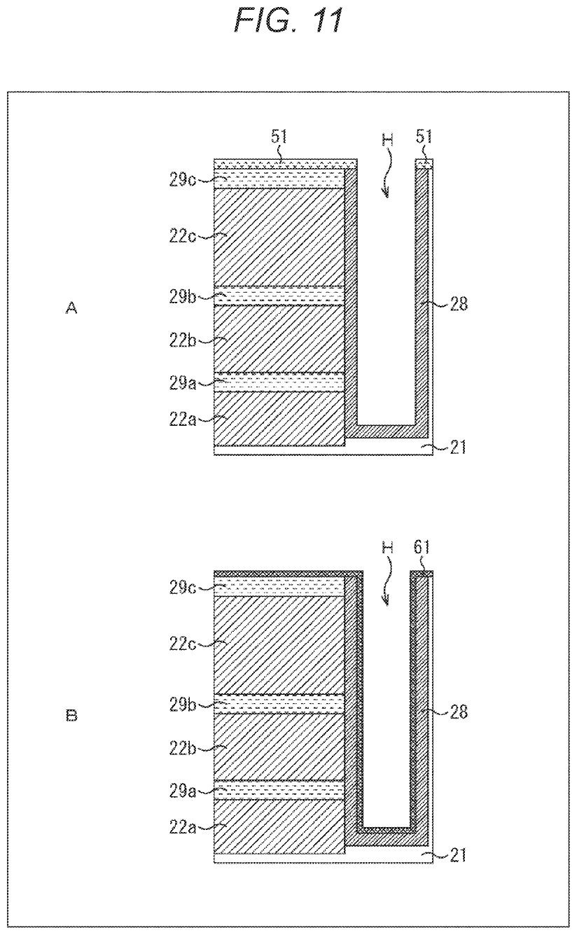

Next, as illustrated in A of FIG. 11, the charge transfer layer 28 is formed at a predetermined depth in each direction of the bottom surface and the side wall of the recess H of the semiconductor substrate 21 by solid-phase diffusion, ion implantation or the like.

Thereafter, after the mask 51 is removed by wet etching or the like, as illustrated in B of FIG. 11, a silicon oxide film 61 for forming the gate insulating film 27a is formed by thermal oxidation so as to cover the recess H and the upper surface of the circuit formation surface.

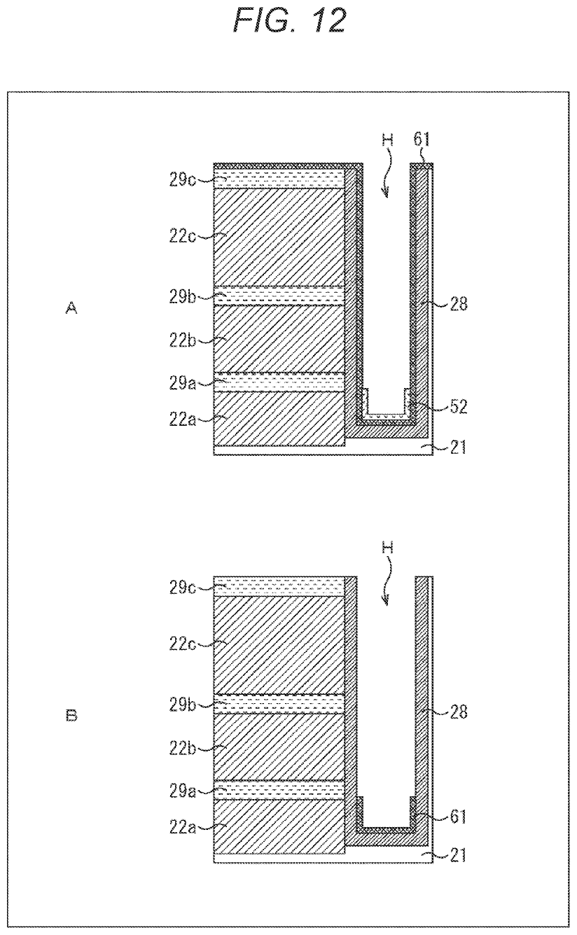

Next, as illustrated in A of FIG. 12, a mask 52 is formed by using, for example, silicon nitride or the like in a region in which the gate insulating film 27a is to be formed on the silicon oxide film 61. At that time, the mask 52 is formed by, for example, forming silicon nitride by a CVD method or the like so as to cover the bottom surface and the side wall of the recess H, and then entirely etching the same by wet etching or the like so as to leave a predetermined depth of the recess H (region in which the gate insulating film 27a is to be formed).

Thereafter, the silicon oxide film 61 is peeled off by wet etching or the like. Then, when the mask 52 is removed, as illustrated in B of FIG. 12, a structure in which the silicon oxide film 61 remains only in the region in which the gate insulating film 27a is to be formed is formed.

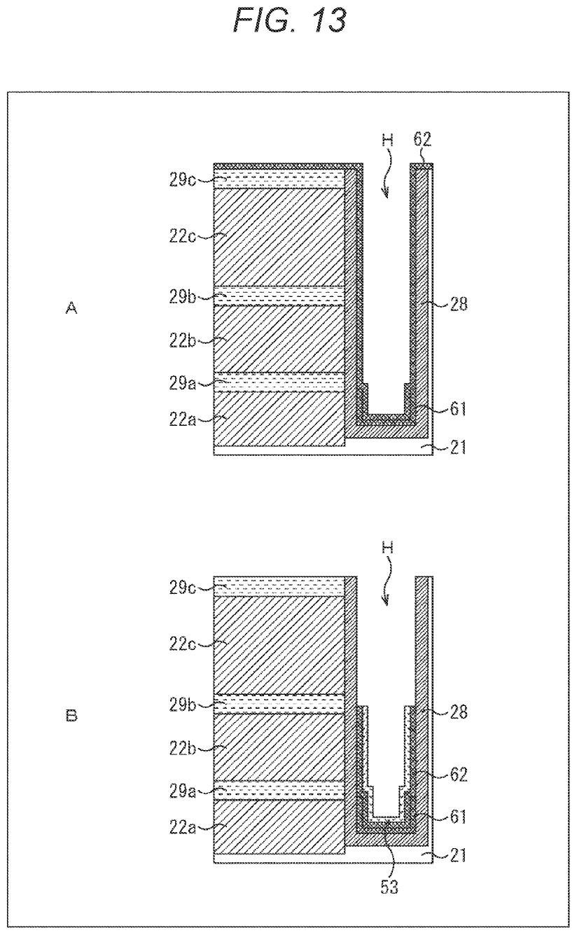

Next, as illustrated in A of FIG. 13, when a silicon oxide film 62 is formed again by thermal oxidation, a structure in which the silicon oxide film in the region in which the gate insulating film 27a is to be formed (region in which the mask 52 is formed) is thicker is formed.

Subsequently, as in the case of forming the mask 52, after a mask 53 is formed in the region in which the gate insulating films 27a and 27b are to be formed on the silicon oxide film 62, the silicon oxide film 62 is peeled off by wet etching or the like as illustrated in B of FIG. 13.

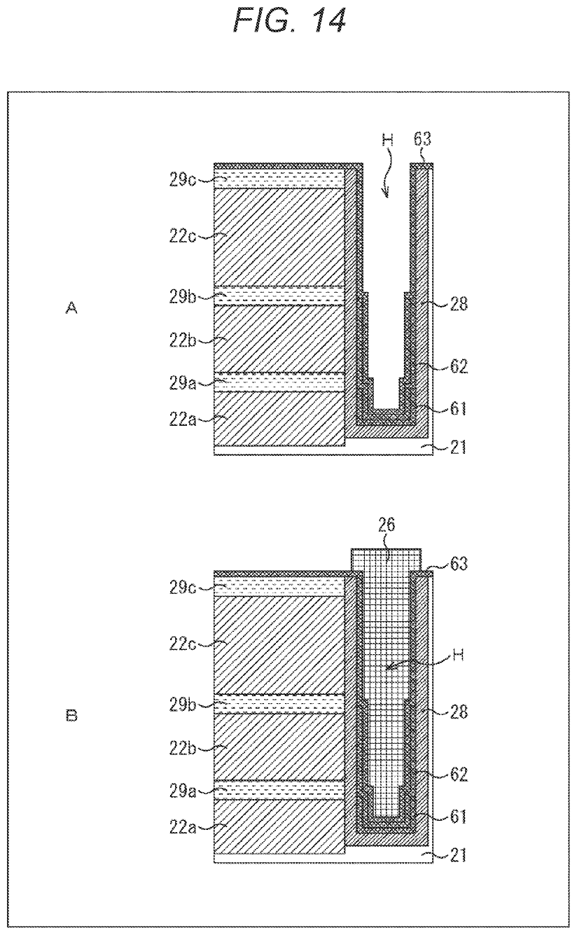

Thereafter, when the mask 53 is removed and the silicon oxide film 63 is formed again by thermal oxidation, as illustrated in A of FIG. 14, the gate insulating film 27 having different film thicknesses is formed by using the three layers of silicon oxide films 61 to 63. In A of FIG. 14, a portion where the three layers of the silicon oxide films 61 to 63 are formed corresponds to the gate insulating film 27a in FIG. 4, a portion where two layers of the silicon oxide films 62 and 63 are formed corresponds to the gate insulating film 27b in FIG. 4, and a portion where one layer of the silicon oxide film 63 is formed corresponds to the gate insulating film 27c in FIG. 4. Note that, the gate insulating film 27 of four or more stages having different film thicknesses may also be formed. In this case, as described above, by further repeating the formation of the silicon oxide film, the formation of the mask, the peeling of the silicon oxide film, and the removal of the mask, the gate insulating film 27 of four or more stages may be formed.

After the gate insulating film 27 of optional number of stages is formed, a polysilicon film is formed so as to fill the recess H by a CVD method or the like, and the polysilicon film is doped with high-concentration impurities. Thereafter, the gate electrode 26 is formed as illustrated in B of FIG. 14 by patterning into a predetermined shape by etching using a photolithography method or the like.

As described above, the vertical transistor 24 having different film thicknesses of the gate insulating film 27 (27a to 27c) is formed corresponding to the three photodiodes 22a to 22c. After the vertical transistor 24 is formed, the on-chip lens 23, the FD 25, the wiring 30, the read wiring 31 and the like illustrated in FIG. 2 are formed.

By the method of forming described above, the pixel 2 including the vertical transistor 24 according to the first structure may be formed. Therefore, even in a case where the pixel is miniaturized, the sensitivity may be improved, and signals of respective colors of R, G, and B may be individually output by one pixel.

### Second Structural Example

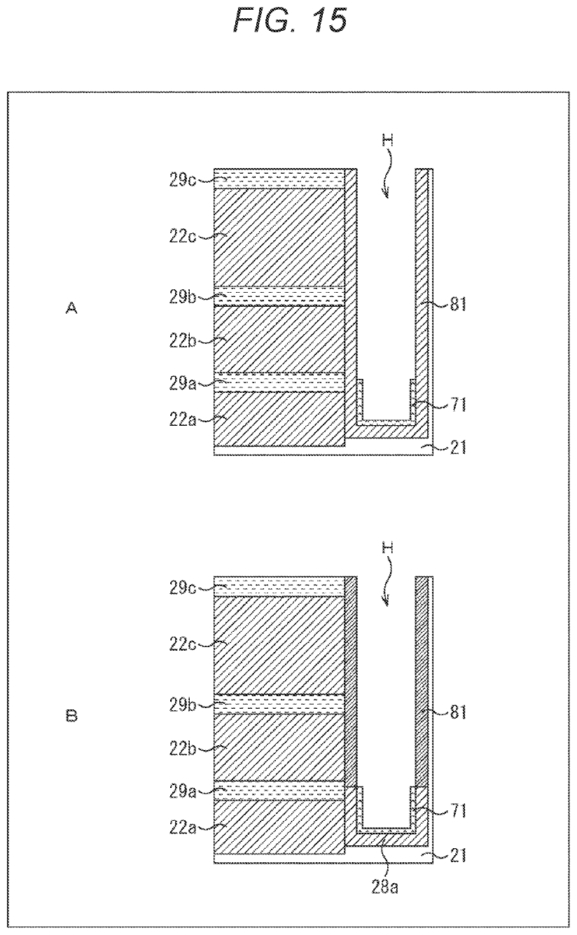

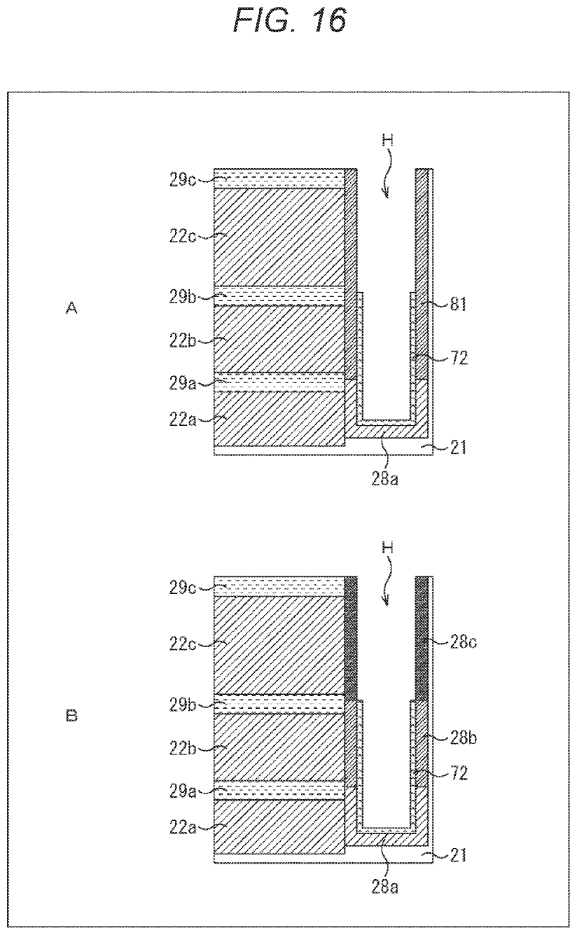

Next, a method of forming the pixel 2 including the vertical transistor 24 according to a second structure is described with reference to FIGS. 15 and 16.

The pixel 2 including the vertical transistor 24 according to the second structure is formed by a method similar to the method of forming the pixel 2 including the vertical transistor 24 according to the first structure described above, except that a method of forming the charge transfer layer 28 and the gate insulating film 27 is different. Hereinafter, it is described while appropriately omitting a point overlapping with the method of forming the pixel 2 including the vertical transistor 24 according to the first structure.

After the recess H is formed as described with reference to B of FIG. 10, a charge transfer layer 81 is formed at a predetermined depth in each direction of the bottom surface and the side wall of the recess H of the semiconductor substrate 21 by solid-phase diffusion, ion implantation or the like. Thereafter, as illustrated in A of FIG. 15, a mask 71 is formed by using, for example, silicon nitride or the like in a region in which the charge transfer layer 28a is to be formed on the charge transfer layer 81.

At that time, the mask 71 is formed by, for example, forming silicon nitride by a CVD method or the like so as to cover the bottom surface and the side wall of the recess H, and then entirely etching the same by wet etching or the like so as to leave a predetermined depth of the recess H (region in which the charge transfer layer 28a is to be formed).

Thereafter, when doping with the impurities again by solid-phase diffusion or the like, as illustrated in B of FIG. 15, the charge transfer layer 81 covered with the mask 71 directly becomes the charge transfer layer 28a having the lowest impurity concentration, and the impurity concentration of the charge transfer layer 81 not covered with the mask 71 becomes higher than that of the charge transfer layer 28a.

After the mask 71 is removed, as illustrated in A of FIG. 16, a mask 72 is formed on the charge transfer layer 28a and in a region in which the charge transfer layer 28b is to be formed on the charge transfer layer 81, as in the case where the mask 71 is formed.

Next, as illustrated in B of FIG. 16, when doping with the impurities again by solid-phase diffusion or the like, the charge transfer layer 81 covered with the mask 72 directly becomes the charge transfer layer 28b having the second lowest impurity concentration. Furthermore, the impurity concentration of the charge transfer layer 81 not covered with the mask 72 becomes higher than that of the charge transfer layer 28b, and the charge transfer layer 28c having the highest impurity concentration is formed.

Thereafter, when the mask 72 is removed by wet etching or the like, the three stages of charge transfer layers 28 (28a to 28c) having different impurity concentrations is formed. Note that, the charge transfer layer 28 of four or more stages having different impurity concentrations may also be formed. In this case, as described above, by further repeating the formation of the mask, the doping with the impurities, and the removal of the mask, the charge transfer layer 28 of four or more stages may be formed.

After the charge transfer layers 28a to 28c are formed, a silicon oxide film is formed by thermal oxidation so as to cover the recess H and the upper surface of the circuit formation surface, so that the gate insulating film 27 is formed with the same film thickness. Thereafter, when the gate electrode 26 is formed by a method similar to that of the method forming the pixel 2 including the vertical transistor 24 according to the first structure, the vertical transistor 24 according to the second structure is formed.

### Third Structural Example

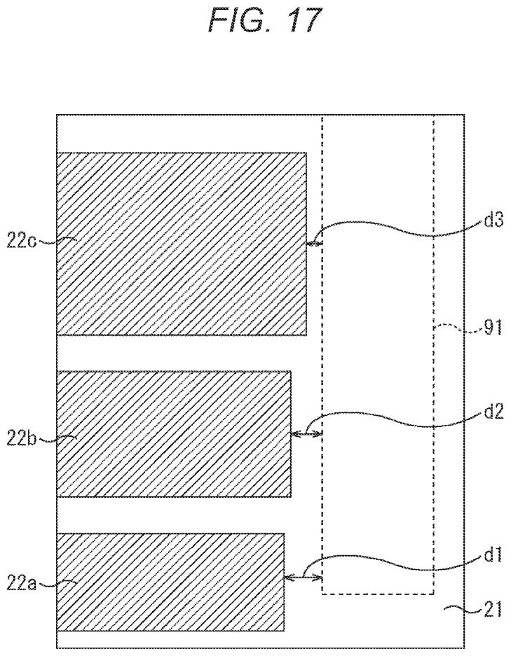

Next, a method of forming the pixel 2 including the vertical transistor 24 according to the third structure is described with reference to FIG. 17.

The pixel 2 including the vertical transistor 24 according to the third structure is formed by a method similar to the method of forming the pixel 2 including the vertical transistor 24 according to the first structure described above, except that the method of forming the photodiodes 22a to 22c is different and the gate insulating film 27 is formed with the same film thickness. Hereinafter, it is described while appropriately omitting a point overlapping with the method of forming the pixel 2 including the vertical transistor 24 according to the first structure.

First, as illustrated in FIG. 17, by doping the semiconductor substrate 21 with n-type impurities by ion implantation or the like, the photodiodes 22a to 22c are formed at different depths of the semiconductor substrate 21. At that time, the photodiodes 22a to 22c are formed in such a manner that distances between the photodiodes 22a to 22c and a region 91 indicated by a broken line in the substrate plane direction increase in the order of the distance d3, the distance d2, and the distance d1. The region 91 is a region in which the recess H is to be formed.

Thereafter, although not illustrated, the recess H is formed by etching the region 91, and the gate insulating film 27 and the charge transfer layer 28 having the same film thickness in the substrate plane direction regardless of the substrate depth are formed. Subsequently, after the polysilicon film is embedded in the recess H, the polysilicon film is doped with high-concentration impurities, so that the gate electrode 26 is formed, and the vertical transistor 24 according to the third structure is completed.

Note that, it is not necessary to form the photodiodes 22a to 22c in such a manner that the distance increases in the order described above. Out of the photodiodes 22a to 22c, one photodiode 22 that reads the signal charge first is formed with the distance d3 from the region 91 in the substrate plane direction, and one photodiode 22 that reads the signal charge last is formed with the distance d1 from the region 91 in the substrate plane direction.

Furthermore, four or more photodiodes 22 may also be formed in a stacking manner. In this case, they may be formed in such a manner that the distances between the formed photodiodes 22 of the respective layers, and the gate electrode 26 and the gate insulating film 27 are different from one another, or a plurality of layers of photodiodes 22 may be formed at the same distance from the gate electrode 26 and the gate insulating film 27.

According to the method of forming the pixel 2 including the vertical transistor 24 according to the first to third structures described above, it is not necessary to form the semiconductor layer by epitaxial growth after the photodiode is created as in the structure disclosed in Patent Document 2, and this may be formed more easily. Then, even in a case where the pixel is miniaturized, the sensitivity may be improved, and signals of respective colors of R, G, and B may be individually output by one pixel.

<<3. Variation>>

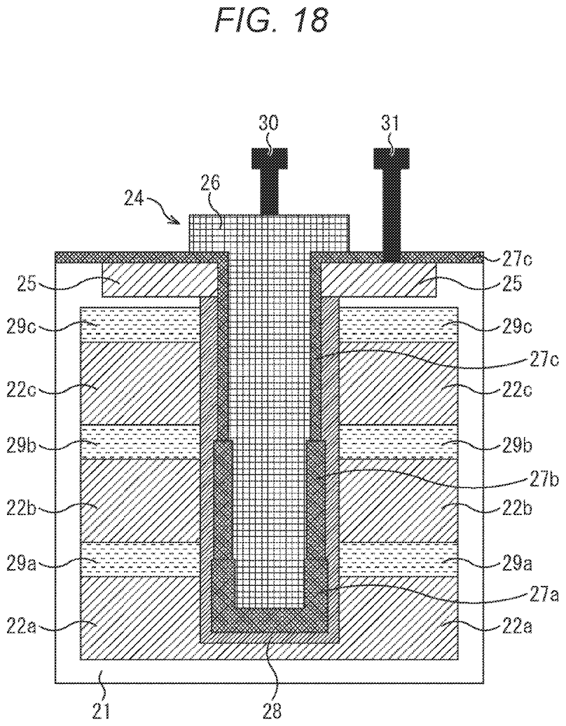

FIG. 18 is a cross-sectional view illustrating a first variation of the pixel 2.

In the basic structure of the pixel 2 described with reference to FIG. 2 and the like, the vertical transistor 24 is arranged adjacent outside of the three photodiodes 22a to 22c formed in the semiconductor substrate 21. In contrast, in the pixel 2 according to the first variation in FIG. 18, the vertical transistor 24 is arranged at the center in the plane direction in the pixel 2, and is formed inside the three photodiodes 22a to 22c. The gate electrode 26 is formed to penetrate the photodiodes 22b and 22c and the element isolation layers 29a to 29c in such a manner that a bottom of the gate electrode 26 reaches the inside of the photodiode 22a. The FD 25 is formed above the element isolation layer 29c so as to surround the gate electrode 26.

The first variation in FIG. 18 has a configuration in which the vertical transistor 24 according to the first structure including the gate insulating films 27a to 27c having different film thicknesses is arranged at the center in the plane direction in the pixel. Similarly, the vertical transistor 24 according to the second structure and the vertical transistor 24 according to the third structure may be arranged at the center in the plane direction in the pixel, and the FD 25 may be arranged above the element isolation layer 29c so as to surround the gate electrode 26.

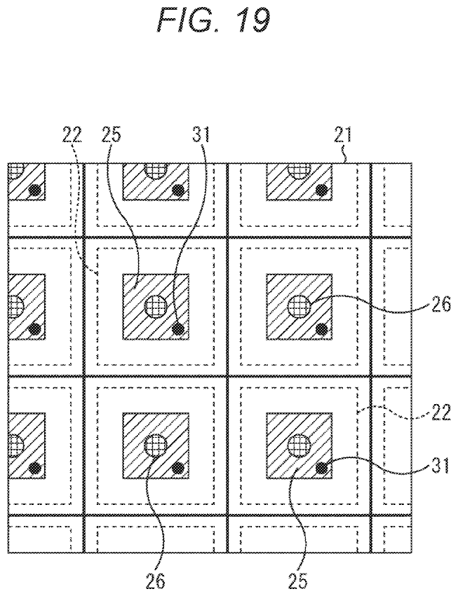

FIG. 19 is a plan view of the semiconductor substrate 21 in which a plurality of pixels 2 according to the first variation is arranged as seen from the circuit formation surface side.

Note that, in FIG. 19, in order to facilitate understanding of an arrangement relationship between the gate electrode 26 of the vertical transistor 24 and the FD 25, the gate insulating film 27 and the wiring 30 on the gate electrode 26 are not illustrated.

The photodiode 22 (photodiodes 22a to 22c) indicated by a broken line in FIG. 19 is formed in a rectangular region at the center of the pixel 2 divided into a lattice pattern. Moreover, the FD 25 is formed in one rectangular region in the pixel center inside the photodiode 22. By forming the FD 25 in one region with respect to the three photodiodes 22a to 22c formed by stacking, it is possible to prevent a significant delay in reading speed.

The gate electrode 26 is formed in a substantially circular shape at the center of the FD 25. The read wiring 31 is formed in a region different from the pixel center in which the gate electrode 26 is arranged on the FD 25.

In this manner, a planar position in the pixel 2 at which the gate electrode 26 of the vertical transistor 24 is formed may be inside the region in which the photodiode 22 is formed or outside the region in which the photodiode 22 is formed.

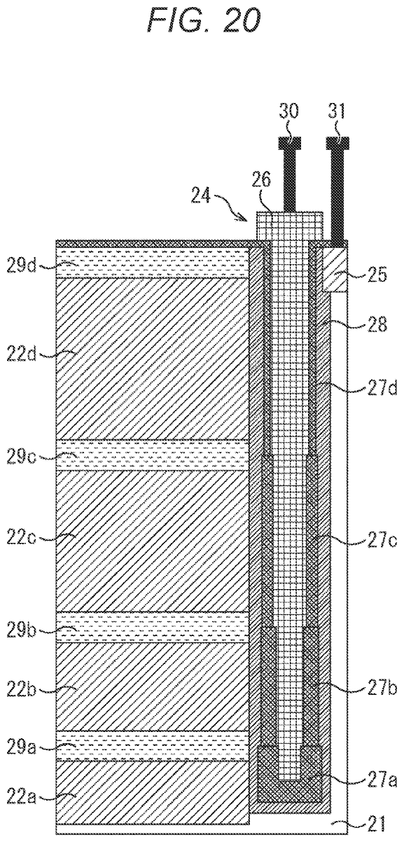

FIG. 20 is a cross-sectional view illustrating a second variation of the pixel 2, an enlarged cross-sectional view of the vicinity of the vertical transistor 24.

The second variation in FIG. 20 has a structure obtained by changing the number of stacked layers of the photodiodes 22 of the pixel 2 including the vertical transistor 24 according to the first structure illustrated in FIG. 4 to four. In other words, as compared with the pixel 2 in FIG. 4, in the second variation in FIG. 20, a photodiode 22d is additionally provided. The photodiode 22d is formed on the circuit formation surface side of the element isolation layer 29c, and an element isolation layer 29d is further formed between the photodiode 22d and the circuit formation surface.

Furthermore, the gate insulating film 27 is also formed by using four stages of gate insulating films 27a to 27d having different film thicknesses corresponding to the four photodiodes 22a to 22d, respectively. The film thickness of the gate insulating film 27d corresponding to the photodiode 22d in the substrate plane direction is made thinner than that of the gate insulating film 27c. That is, the gate insulating films 27a to 27d are formed in such a manner that the film thickness increases in the order of the gate insulating film 27d, the gate insulating film 27c, the gate insulating film 27b, and the gate insulating film 27a (gate insulating film 27d<gate insulating film 27c<gate insulating film 27b<gate insulating film 27a).

The photodiode 22d is formed at a depth at which infrared light reaches in the semiconductor substrate 21, and selectively absorbs the infrared light to perform photoelectric conversion, for example. In other words, the photodiode 22d is a photodiode for obtaining a signal charge corresponding to the infrared light. In this case, the signal charges of the infrared light, red light, green light, and blue light may be individually read by controlling the voltage applied to the gate electrode 26 of the vertical transistor 24.

Note that, in the above-described example, the four photodiodes 22a to 22d are formed so as to be divided into wavelengths of respective colors of the infrared light, red light, green light, and blue light, but the division of the wavelengths photoelectrically converted by the four photodiodes 22a to 22d is not limited thereto. In other words, two regions out of the four photodiodes 22a to 22d may be made regions that photoelectrically convert light of the same color.

For example, the photodiodes 22a to 22d may be formed in such a manner that the photodiode 22a absorbs blue light (B), the photodiode 22b absorbs green light (Gb) having a short wavelength, the photodiode 22c absorbs green light (Gr) having a long wavelength, and the photodiode 22d absorbs red light (R).

In this case, the gate insulating films 27b and 27c corresponding to the photodiodes 22b and 22c, respectively, that photoelectrically convert light of the same color (green light) are formed to have the same film thickness. In other words, the gate insulating film 27 is formed with a uniform film thickness with respect to the two photodiodes 22b and 22c. Therefore, after the signal charge accumulated in the photodiode 22a is individually read, the signal charges accumulated in the photodiodes 22b and 22c are simultaneously read. After the signal charges accumulated in the photodiodes 22b and 22c are read, the signal charge accumulated in the photodiode 22d is individually read.

Since the photodiodes 22b and 22c are formed so as to absorb the green light, it is possible to increase the signal charge capacity of the green light.

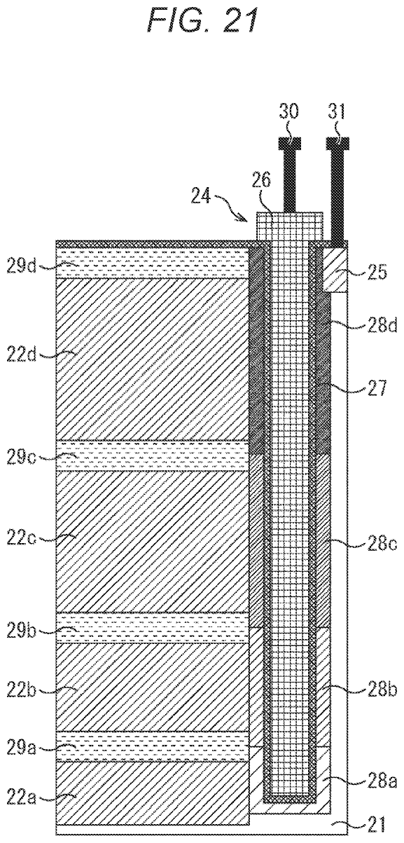

FIG. 21 is a cross-sectional view illustrating a third variation of the pixel 2, an enlarged cross-sectional view of the vicinity of the vertical transistor 24.

In the third variation in FIG. 21, as in the second variation in FIG. 20, the four photodiodes 22a to 22d are formed in a stacking manner. Then, the third variation in FIG. 21 includes the vertical transistor 24 according to the second structure illustrated in FIG. 7, and four stages of the charge transfer layers 28a to 28d having different impurity concentrations are formed corresponding to the four photodiodes 22a to 22d, respectively.

The charge transfer layer 28d corresponding to the photodiode 22d is formed at an impurity concentration higher than that of the charge transfer layer 28c. That is, the charge transfer layers 28a to 28d are formed in such a manner that the impurity concentration increases in the order of the charge transfer layer 28a, the charge transfer layer 28b, the charge transfer layer 28c, and the charge transfer layer 28d (charge transfer layer 28a<charge transfer layer 28b<charge transfer layer 28c<charge transfer layer 28d).

Also in the third variation, the four photodiodes 22a to 22d may be made regions that photoelectrically convert light having wavelengths of different colors such as infrared light, red light, green light, and blue light, or the two photodiodes 22b and 22c out of the four photodiodes 22a to 22d may be made regions that photoelectrically convert light of the same color (green) such as blue light (B), green light (Gb) having a short wavelength, green light (Gr) having a long wavelength, and red light (R). In this case, the impurity concentrations of the charge transfer layers 28b and 28c corresponding to the two photodiodes 22b and 22c that photoelectrically convert light of the same color are formed at uniform concentrations.

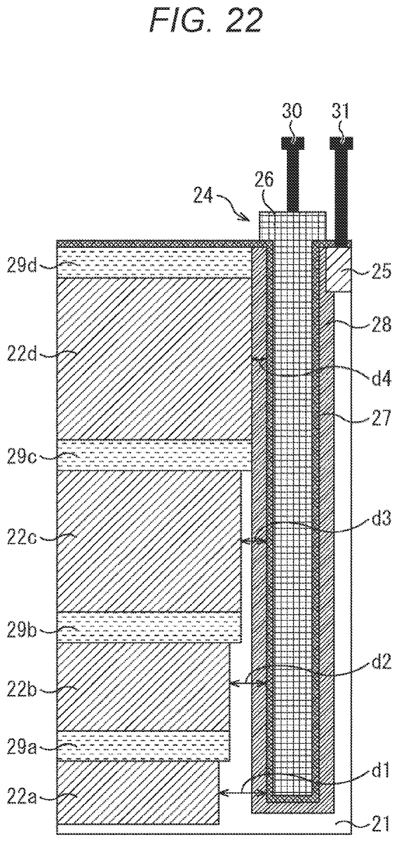

FIG. 22 is a cross-sectional view illustrating a fourth variation of the pixel 2, an enlarged cross-sectional view of the vicinity of the vertical transistor 24.

In the fourth variation in FIG. 22, as in the second variation in FIG. 20 and the third variation in FIG. 21, the four photodiodes 22a to 22d are formed in a stacking manner. Then, the fourth variation in FIG. 22 includes the vertical transistor 24 according to the third structure illustrated in FIG. 8 and is formed in such a manner that the distances between the four photodiodes 22a to 22d, and the gate electrode 26 and the gate insulating film 27 are different from one another.

The photodiode 22d is formed in such a manner that a distance d4 to the gate insulating film 27 is smaller than the distance d3 between the photodiode 22c and the gate insulating film 27. That is, the photodiodes 22a to 22d are formed in such a manner that the distance increases in the order of the distance d4, the distance d3, the distance d2, and the distance d1 (distance d4<distance d3<distance d2<distance d1).

In FIG. 22, unlike the third structure illustrated in FIG. 8, the charge transfer layer 28 is formed with a constant thickness. More specifically, in the third structure illustrated in FIG. 8, all the regions of the distances d3, d2, and d1 between the photodiodes 22a to 22c and the gate insulating film 27 include the charge transfer layer 28, and the charge transfer layer 28 has different thicknesses. In contrast, in the fourth variation in FIG. 22, only the charge transfer layer 28 is formed between the photodiode 22d and the gate insulating film 27, and the charge transfer layer 28 and a layer of the semiconductor substrate 21 are formed between the photodiodes 22a to 22c and the gate insulating film 27. In this manner, the distance between the photodiode 22 and the gate insulating film 27 may be adjusted by forming not only the charge transfer layer 28 but also the layer of the semiconductor substrate 21 between the photodiode 22 and the gate insulating film 27.

Also in the fourth variation, the four photodiodes 22a to 22d may be made regions that photoelectrically convert light having wavelengths of different colors such as infrared light, red light, green light, and blue light, or the two photodiodes 22b and 22c out of the four photodiodes 22a to 22d may be made regions that photoelectrically convert light of the same color (green) such as blue light (B), green light (Gb) having a short wavelength, green light (Gr) having a long wavelength, and red light (R). In this case, the distance between the two photodiodes 22b and 22c that photoelectrically convert light of the same color and the gate insulating film 27 is made uniform.

As described above, the signal charges may be individually read from the stacked photodiodes 22 by forming one vertical transistor 24 for the four stacked photodiodes 22. Note that, in the above-described example, the configuration in which the photodiodes 22 are stacked in three or four layers is described, but a configuration in which one vertical transistor 24 is formed for two stacked photodiodes 22 is also possible, and a configuration in which one vertical transistor 24 is formed for five or more stacked photodiodes 22 is also possible. In a case where three or more photodiodes 22 are stacked in the pixel, the film thickness of the gate insulating film 27, the impurity concentration of the charge transfer layer 28, or the distance d between the photodiode 22 and the gate electrode 26 or the gate insulating film 27 may be made uniform for two or more photodiodes 22, and the accumulated charges may be read simultaneously.

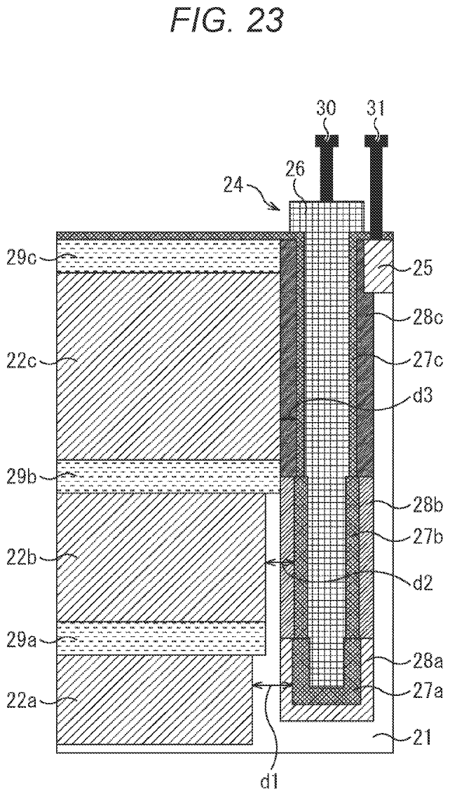

FIG. 23 is a cross-sectional view illustrating a fifth variation of the pixel 2, an enlarged cross-sectional view of the vicinity of the vertical transistor 24.

The pixel 2 according to the fifth variation in FIG. 23 includes the vertical transistor 24 obtained by combining the first structure, the second structure, and the third structure described above.

That is, in the vertical transistor 24 in FIG. 23, the gate insulating films 27a to 27c having different film thicknesses in the substrate plane direction are formed and the charge transfer layers 28a to 28c having different impurity concentrations are formed corresponding to the three stacked photodiodes 22a to 22c. Moreover, the photodiodes 22a to 22c are formed in such a manner that the distances d1 to d3 from the gate insulating films 27a to 27c are different.

In this manner, the vertical transistor 24 may have a structure in which all or any two of the first structure, the second structure, and the third structure described above are combined. Therefore, accuracy when individually reading the signal charges accumulated in the photodiodes 22a to 22c may be further improved.

<<4. Application Example to Electronic Device>>

The solid-state imaging element 1 described above is applicable to various electronic devices such as, for example, an imaging device such as a digital still camera and a digital video camera, a mobile phone with an imaging function, or other devices having an imaging function.

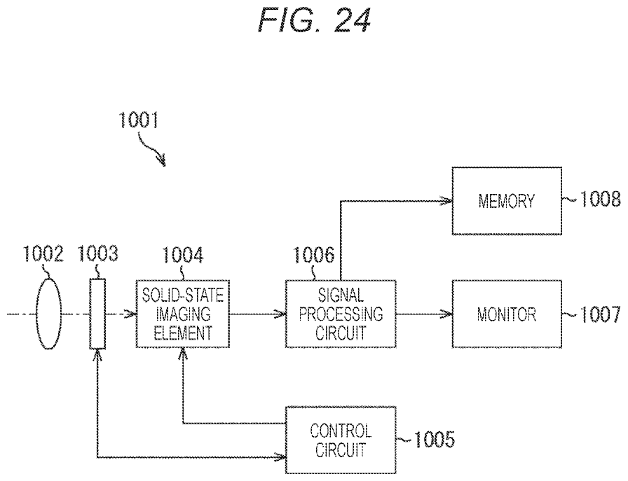

FIG. 24 is a block diagram depicting a configuration example of an imaging device as an electronic device to which an embodiment of the present disclosure is applied.

An imaging device 1001 illustrated in FIG. 24 provided with an optical system 1002, a shutter device 1003, a solid-state imaging element 1004, a drive circuit 1005, a signal processing circuit 1006, a monitor 1007, and a memory 1008 may image a still image and a moving image.

The optical system 1002 including one or a plurality of lenses guides light from a subject (incident light) to the solid-state imaging element 1004 to form an image on a light-receiving surface of the solid-state imaging element 1004.

The shutter device 1003 arranged between the optical system 1002 and the solid-state imaging element 1004 controls a light emission period to the solid-state imaging element 1004 and a light-shielding period according to control of the drive circuit 1005.

The solid-state imaging element 1004 includes the above-described solid-state imaging element 1. The solid-state imaging element 1004 accumulates a signal charge for a certain period according to the light the image of which is formed on the light-receiving surface via the optical system 1002 and the shutter device 1003. The signal charge accumulated in the solid-state imaging element 1004 is transferred according to a drive signal (timing signal) supplied from the drive circuit 1005. The solid-state imaging element 1004 may be formed as one chip alone or may be formed as a part of a camera module packaged together with the optical system 1002 to the signal processing circuit 1006 and the like.

The drive circuit 1005 outputs the drive signal to control a transfer operation of the solid-state imaging element 1004 and a shutter operation of the shutter device 1003 to drive the solid-state imaging element 1004 and the shutter device 1003.

The signal processing circuit 1006 performs various kinds of signal processing on the signal charge output from the solid-state imaging element 1004. The image (image data) obtained by the signal processing applied by the signal processing circuit 1006 is supplied to the monitor 1007 to be displayed or supplied to the memory 1008 to be stored (recorded).

Also in the imaging device 1001 configured in this manner, by applying the above-described solid-state imaging element 1 as the solid-state imaging element 1004, even in a case where pixels are miniaturized, sensitivity may be improved, and signals of respective colors of R, G, and B may be individually output by one pixel.

<<5. Usage Example of Imaging Device>>

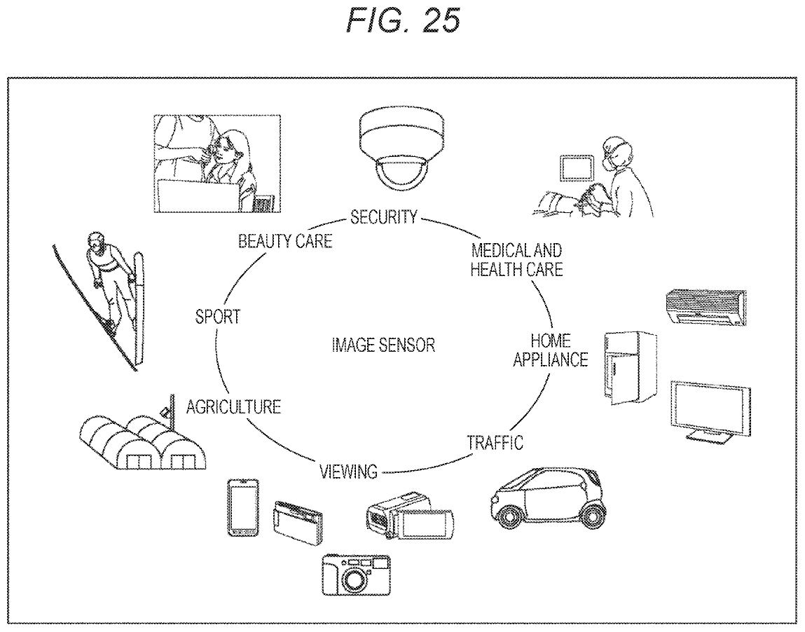

FIG. 25 is a diagram illustrating a usage example of using the above-described imaging device 1001.

The above-described imaging device 1001 may be used in various cases where light such as visible light, infrared light, ultraviolet light, and X-ray is sensed as described below, for example.
A device that images an image to be used for viewing such as a digital camera and a portable device with a camera function
A device for traffic purpose such as an in-vehicle sensor that images the front, rear, surroundings, inside and the like of an automobile, a surveillance camera for monitoring traveling vehicles and roads, and a ranging sensor that measures a distance between vehicles and the like for safe driving such as automatic stop, recognition of a state of a driver and the like.
A device for home appliance such as a television, a refrigerator, and an air conditioner that images a user's gesture and performs a device operation according to the gesture
A device for medical and health care use such as an endoscope and a device that performs angiography by receiving infrared light
A device for security use such as a security monitoring camera and an individual authentication camera
A device for beauty care such as a skin measuring device that images skin and a microscope that images scalp
A device for sporting use such as an action camera and a wearable camera for sporting use and the like
A device for agricultural use such as a camera for monitoring land and crop states

<<6. Application Example to Mobile Body>>

The technology according to an embodiment of the present disclosure (present technology) may be applied to various products. For example, the technology according to an embodiment of the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

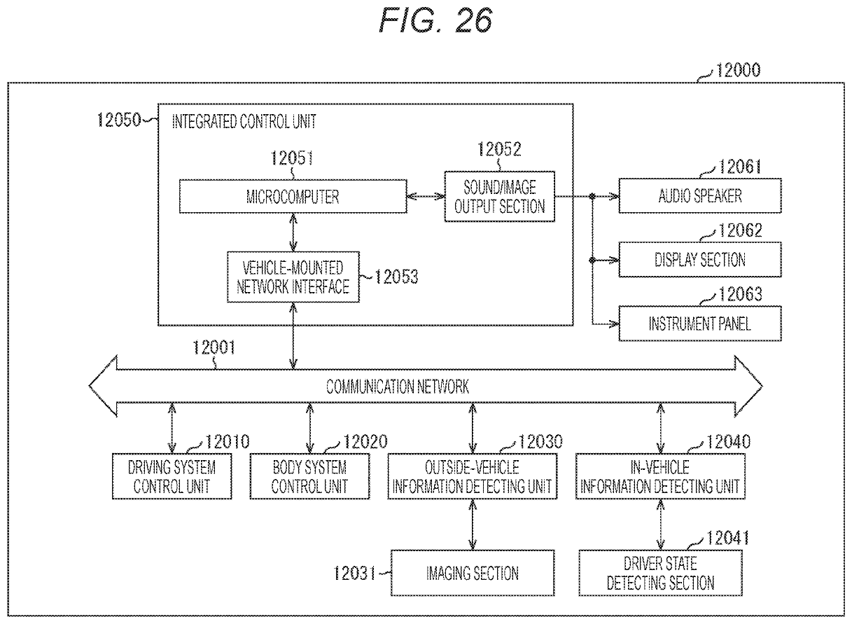

FIG. 26 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example illustrated in FIG. 26, the vehicle control system 12000 is provided with a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 26, as the output device, an audio speaker 12061, a display section 12062, and an instrument panel 12063 are illustrated. The display section 12062 may, for example, include at least one of an on-board display and a head-up display.

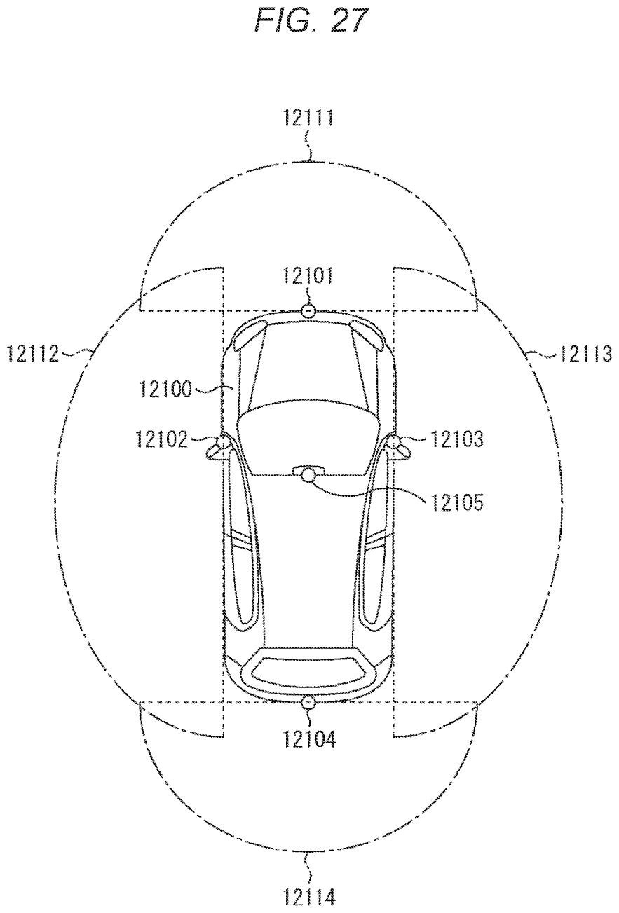

FIG. 27 is a diagram illustrating an example of an installation position of the imaging section 12031.

In FIG. 27, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, FIG. 27 illustrates an example of imaging range of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to an embodiment of the present disclosure can be applied has been described above. The technology according to an embodiment of the present disclosure can be applied to the imaging section 12031, for example, of the configurations described above. Specifically, the solid-state imaging element 1 described above is applicable to the imaging section 12031, for example. By applying the technology according to an embodiment of the present disclosure to the imaging section 12031, it is possible to increase the resolution of the imaging section 12031 and to reduce a size and improve the sensitivity due to miniaturization of pixels.

Note that, the effects described in the present specification are merely examples and are not limited, and there may be other effects.

The embodiments of the present technology are not limited to the above-described embodiments, and various modifications may be made without departing from the scope of the present technology.

For example, although the solid-state imaging element in which the first conductivity type is the P-type and the second conductivity type is the N-type, and an electron is used as a signal charge is described in the above-described example, the present technology is also applicable to the solid-state imaging element in which a positive hole is used as the signal charge. In this case, the first conductivity type is the N-type, the second conductivity type is the P-type, and the conductivity types of the above-described respective semiconductor regions are reversed.

<Combination Example of Configurations>

The present technology may also have the following configurations.

(1)

A solid-state imaging element including:

a plurality of photodiodes stacked in a semiconductor substrate in a thickness direction of the semiconductor substrate; and

a transistor including a gate electrode at least a part of which is embedded in the semiconductor substrate, the transistor that individually reads a signal charge accumulated in each of the plurality of photodiodes according to a voltage applied to the gate electrode.

(2)

The solid-state imaging element according to (1) described above, in which

the transistor further includes a plurality of stages of gate insulating films having different film thicknesses in a substrate plane direction of the semiconductor substrate, and

each stage of the gate insulating films is formed with a uniform film thickness with respect to at least one of the plurality of photodiodes.

(3)

The solid-state imaging element according to (2) describe above, in which each stage of the gate insulating films is formed with a uniform film thickness with respect to one of the plurality of photodiodes.

(4)

The solid-state imaging element according to (2) described above, in which

the plurality of stages of gate insulating films includes a gate insulating film formed with a uniform film thickness with respect to at least two of the plurality of photodiodes.

(5)

The solid-state imaging element according to (1) or (2) described above, in which

the transistor further includes a plurality of stages of charge transfer layers having different impurity concentrations between the plurality of photodiodes and the gate electrode, and

each stage of the charge transfer layers is formed at a uniform impurity concentration with respect to at least one of the plurality of photodiodes.

(6)

The solid-state imaging element according to (5) described above, in which

each stage of the charge transfer layers is formed at a uniform impurity concentration with respect to one of the plurality of photodiodes.

(7)

The solid-state imaging element according to (5) described above, in which

the plurality of stages of charge transfer layers includes a charge transfer layer formed at a uniform impurity concentration with respect to at least two of the plurality of photodiodes.

(8)

The solid-state imaging element according to any one of (1), (2), and (5), in which

each of the plurality of photodiodes is formed at a position where a distance from the gate electrode or a gate insulating film of the transistor is different from the distance of any of other photodiodes.

(9)

The solid-state imaging element according to (8) described above, in which

each of the plurality of photodiodes is formed at a position where the distance from the gate electrode or the gate insulating film is different from the distance of all other photodiodes.

(10)

The solid-state imaging element according to (8) described above, in which

the plurality of photodiodes includes a photodiode formed at a position where the distance from the gate electrode or the gate insulating film is uniform with the distance of at least one of other photodiodes.

(11)

The solid-state imaging element according to any one of (1) to (10) described above, in which

the plurality of photodiodes includes a photodiode for obtaining a signal charge corresponding to blue light, a photodiode for obtaining a signal charge corresponding to green light, and a photodiode for obtaining a signal charge corresponding to red light in this order from a light-receiving surface side of the semiconductor substrate.

(12)

The solid-state imaging element according to (11) described above, in which

the plurality of photodiodes further includes a photodiode for obtaining a signal charge corresponding to infrared light on a side closer to the light-receiving surface than the photodiode for obtaining a signal charge corresponding to red light.

(13)

The solid-state imaging element according to any one of (1) to (12) described above, in which

the gate electrode is embedded in a recess formed to a depth reaching a photodiode closest to a light-receiving surface side out of the plurality of photodiodes.

(14)

The solid-state imaging element according to any one of (1) to (13) described above, in which

the transistor is provided on a circuit formation surface side on a side opposite to a light-receiving surface of the semiconductor substrate, and sequentially reads signal charges accumulated in the plurality of photodiodes from the circuit formation surface side.

(15)

The solid-state imaging element according to any one of (1), (2), (4), (5), (7), (8), and (10) to (14), in which

the transistor simultaneously reads signal charges accumulated in at least two or more photodiodes out of the plurality of photodiodes according to a predetermined voltage applied to the gate electrode.

(16)

A method of manufacturing a solid-state imaging element including:

stacking a plurality of photodiodes in a semiconductor substrate in a thickness direction of the semiconductor substrate; and

forming a transistor including a gate electrode at least a part of which is embedded in the semiconductor substrate, the transistor that individually reads a signal charge accumulated in each of the plurality of photodiodes according to a voltage applied to the gate electrode.

(17)

An electronic device including:

a solid-state imaging element including:

a plurality of photodiodes stacked in a semiconductor substrate in a thickness direction of the semiconductor substrate; and

a transistor including a gate electrode at least a part of which is embedded in the semiconductor substrate, the transistor that individually reads a signal charge accumulated in each of the plurality of photodiodes according to a voltage applied to the gate electrode.

### REFERENCE SIGNS LIST

1 Solid-state imaging element
2 Pixel
21 Semiconductor substrate
22a to 22d Photodiode
23 On-chip lens
24 Vertical transistor
25 FD
26 Gate electrode
27, 27a to 27d Gate insulating film
28, 28a to 28d Charge transfer layer
29, 29a to 29d Element isolation layer
30 Wiring
31 Read wiring

What is claimed is:

1. A solid-state imaging element, comprising:
a plurality of photodiodes stacked in a semiconductor substrate in a thickness direction of the semiconductor substrate; and
a transistor including a gate electrode at least a part of which is embedded in the semiconductor substrate, the transistor that individually reads a signal charge accumulated in each of the plurality of photodiodes according to a voltage applied to the gate electrode.

2. The solid-state imaging element according to claim 1, wherein
the transistor further includes a plurality of stages of gate insulating films having different film thicknesses in a substrate plane direction of the semiconductor substrate, and
each stage of the gate insulating films is formed with a uniform film thickness with respect to at least one of the plurality of photodiodes.

3. The solid-state imaging element according to claim 2, wherein
each stage of the gate insulating films is formed with a uniform film thickness with respect to one of the plurality of photodiodes.

4. The solid-state imaging element according to claim 2, wherein
the plurality of stages of gate insulating films includes a gate insulating film formed with a uniform film thickness with respect to at least two of the plurality of photodiodes.

5. The solid-state imaging element according to claim 1, wherein
the transistor further includes a plurality of stages of charge transfer layers having different impurity concentrations between the plurality of photodiodes and the gate electrode, and
each stage of the charge transfer layers is formed at a uniform impurity concentration with respect to at least one of the plurality of photodiodes.

6. The solid-state imaging element according to claim wherein
each stage of the charge transfer layers is formed at a uniform impurity concentration with respect to one of the plurality of photodiodes.

7. The solid-state imaging element according to claim wherein
the plurality of stages of charge transfer layers includes a charge transfer layer formed at a uniform impurity concentration with respect to at least two of the plurality of photodiodes.

8. The solid-state imaging element according to claim 1, wherein
each of the plurality of photodiodes is formed at a position where a distance from the gate electrode or a gate insulating film of the transistor is different from the distance of any of other photodiodes.

9. The solid-state imaging element according to claim 8, wherein
each of the plurality of photodiodes is formed at a position where the distance from the gate electrode or the gate insulating film is different from the distance of all other photodiodes.

10. The solid-state imaging element according to claim 8, wherein
the plurality of photodiodes includes a photodiode formed at a position where the distance from the gate electrode or the gate insulating film is uniform with the distance of at least one of other photodiodes.

11. The solid-state imaging element according to claim 1, wherein
the plurality of photodiodes includes a photodiode for obtaining a signal charge corresponding to blue light, a photodiode for obtaining a signal charge corresponding to green light, and a photodiode for obtaining a signal charge corresponding to red light in this order from a light-receiving surface side of the semiconductor substrate.

12. The solid-state imaging element according to claim 11, wherein
the plurality of photodiodes further includes a photodiode for obtaining a signal charge corresponding to infrared light on a side closer to the light-receiving surface than the photodiode for obtaining a signal charge corresponding to red light.

13. The solid-state imaging element according to claim 1, wherein
the gate electrode is embedded in a recess formed to a depth reaching a photodiode closest to a light-receiving surface side out of the plurality of photodiodes.

14. The solid-state imaging element according to claim 1, wherein
the transistor is provided on a circuit formation surface side on a side opposite to a light-receiving surface of the semiconductor substrate, and sequentially reads signal charges accumulated in the plurality of photodiodes from the circuit formation surface side.

15. The solid-state imaging element according to claim 1, wherein
the transistor simultaneously reads signal charges accumulated in at least two or more photodiodes out of the plurality of photodiodes according to a predetermined voltage applied to the gate electrode.

16. A method of manufacturing a solid-state imaging element, comprising:
stacking a plurality of photodiodes in a semiconductor substrate in a thickness direction of the semiconductor substrate; and
forming a transistor including a gate electrode at least a part of which is embedded in the semiconductor substrate, the transistor that individually reads a signal charge accumulated in each of the plurality of photodiodes according to a voltage applied to the gate electrode.

17. An electronic device comprising:
a solid-state imaging element including:
a plurality of photodiodes stacked in a semiconductor substrate in a thickness direction of the semiconductor substrate; and
a transistor including a gate electrode at least a part of which is embedded in the semiconductor substrate, the transistor that individually reads a signal charge accumulated in each of the plurality of photodiodes according to a voltage applied to the gate electrode.
